(19) United States
(12) Patent Application Publication
(10) Pub. No.: US 2012/0076949 A1
(43) Pub. Date: Mar. 29, 2012

(54) PATTERN FORMING METHOD AND PATTERN FORMING APPARATUS

(76) Inventors: Masanobu IWASHIMA, Kyoto (JP); Masakazu SANADA, Kyoto (JP); Koji FURUICHI, Kyoto (JP)

(21) Appl. No.: 13/216,785

(22) Filed: Aug. 24, 2011

(30) Foreign Application Priority Data
Sep. 28, 2010 (JP) 2010-217311

(51) Int. Cl. C08J 7/18; B05C 11/00; B05D 5/00

(52) U.S. Cl. 427/553; 427/286; 118/696

(57) ABSTRACT

In applying an application liquid onto a substrate and forming a line-like pattern, discharging of the application liquid is initiated from an inward position X0 which is inward from an originally intended start position X1, while keeping the amount of the gap between a nozzle and the substrate to a smaller value G0 than the height of the pattern. Following this, the nozzle moves toward outside the substrate while moving away from the substrate, and the reverses its movement direction at the pattern start position X1. Near a posterior end as well, the nozzle moves closer to the substrate while reducing the discharged quantity of the application liquid, and the movement direction is reversed while moving the nozzle away at a pattern end position X3.

### CROSS REFERENCE TO RELATED APPLICATION

The disclosure of Japanese Patent Application No. 2010-217311 filed on Sep. 28, 2010 including specification, drawings and claims is incorporated herein by reference in its entirety.

### BACKGROUND OF THE INVENTION

1. Field of the Invention

The present invention relates to a pattern forming technique for forming a predetermined pattern on a substrate by applying an application liquid which contains a pattern forming material from a nozzle which moves relative to a surface of the substrate.

2. Description of the Related Art

Among techniques for forming a predetermined pattern on a substrate, a technique which requires discharging an application liquid which contains a pattern forming material from a nozzle which moves relative to a surface of a substrate and applying the application liquid to the substrate is known. As this technique gives rise to changes of the discharged quantity of the application liquid immediately after starting discharging of the application liquid or immediately before the termination of discharging, there is a problem that the application quantity is unstable at the anterior end and/or the posterior end of a pattern.

The technique described in JP06-339656A for instance deals with this problem. According to this technique that requires when a slot-type application head applies an application liquid to an object to thereby form a coating film, the application head which moves along a surface of a substrate stops discharging the application liquid before reaching the posterior end of a pattern. Describing this more specifically, before the application head reaches the posterior end of the pattern, a valve for supplying the application liquid is closed, the application head moves away from the object, and suck-back is performed, in an effort to suppress changes of the film thickness of the coating film due to dripping of the liquid after supplying of the application liquid has been stopped.

However, even when the technique described above is used, depending upon the viscosity of the application liquid, the posterior end of the pattern may swell up or become progressively thin on the contrary. The surface tension of the application liquid may lead to a phenomenon that the application head moving away from the object draws the application liquid thin like a thread (herein referred to as “trailing”). Further, while the timing to start discharging the application liquid and the timing to finish discharging the application liquid change instead of staying constant in accordance with the viscosity of the application liquid, the ambient temperature and the like, it is difficult with the conventional technique described above to deal with changes of the position of the end (the anterior end or the posterior end) of the pattern due to this.

### SUMMARY OF THE INVENTION

The invention has been made in light of the problem above, and aims at providing, in relation to a pattern forming technique which requires that a nozzle which moves relative to a surface of a substrate applies a application liquid containing a pattern forming material and a predetermined pattern is formed on the substrate, a technique for forming a pattern which has a stable width and a stable end position.

A pattern forming method according to an aspect of the present invention comprises: forming a stripe-shaped pattern on a surface of a substrate by discharging an application liquid containing a pattern forming material continuously from a discharge outlet of a nozzle to the surface of the substrate while moving the nozzle along and relative to the surface of the substrate in a predetermined scan movement direction; and stopping the discharge of the application liquid from the discharge outlet while moving the nozzle along the surface of the substrate in an opposite direction to the scan movement direction after a relative position of the nozzle to the surface of the substrate arrives at a predetermined pattern end position.

With the structure according to the invention, after the nozzle which applies the application liquid while moving relative to the surface of the substrate moves to the posterior end position, the nozzle stops discharging the application liquid while moving in the opposite direction. Such a change of the nozzle movement direction will be hereinafter referred to as “turning around”. That is, the nozzle reaches the posterior end position in a condition that the application liquid is discharged in a relatively stable manner, and as the nozzle turns around, the application liquid discharged in an instable quantity right before terminating discharging is applied over a pattern which has already been formed. This accordingly solves the problem of pattern width change at the posterior end of the pattern such as thickening, thinning, trailing, etc., whereby in particular the position of the posterior end of the pattern becomes stable instead of varying. In short, it is possible according to the invention to form a pattern which has a stable width and a stable end position.

A pattern forming method according to another aspect of the present invention, comprises: moving the nozzle along and relative to the surface of the substrate in a predetermined scan movement direction; and discharging an application liquid containing a pattern forming material continuously from a discharge outlet of the nozzle to the surface of the substrate while moving the nozzle in the scan movement direction, thereby forming a stripe-shaped pattern on the surface of the substrate, wherein the nozzle is moved along the surface of the substrate in the opposite direction to the scan movement direction for a predetermined period since a start of discharging, and following this, the nozzle is moved along the surface of the substrate in the scan movement direction.

The structure according to this aspect prevents the application liquid discharged in an unstable quantity right after the start of discharging from forming the anterior end of the pattern. In other words, the nozzle moves in the opposite direction to the scanning movement direction immediately after the start of discharging and the nozzle then turns around and moves in the scanning movement direction, thereby forming a pattern, and therefore, the position at which the nozzle turns around is the position of the anterior end of the pattern. As the application liquid from the nozzle which has turned around is applied over the application liquid which had been applied to the substrate right after the start of discharging, the unstable discharging quantity does not affect the pattern. This prevents varying of the position of the anterior end of the pattern in particular. As described above, according to the invention, it is possible to form a pattern which has a stable width and a stable end position.

A pattern forming apparatus of the present invention comprises: a holder which holds a substrate; a nozzle which comprises a discharge outlet for continuously discharging an application liquid which contains a pattern forming material; and a mover which moves the nozzle along and relative to a surface of the substrate, which is held by the holder, in a predetermined scan movement direction, wherein either right after starting or right before stopping discharging the application liquid from the outlet, the mover moves the nozzle along the surface of the substrate in the opposite direction to the scan movement direction for a predetermined period.

With the structure according to the invention, the nozzle turns around as described above at both or one of the anterior end and the posterior end of the pattern. Hence, it is possible to form a stable pattern while suppressing varying of the width and the height of the pattern at the anterior end and the posterior end and varying of the pattern forming position.

The above and further objects and novel features of the invention will more fully appear from the following detailed description when the same is read in connection with the accompanying drawing. It is to be expressly understood, however, that the drawing is for purpose of illustration only and is not intended as a definition of the limits of the invention.

### BRIEF DESCRIPTION OF THE DRAWINGS

FIG. 1 is a drawing which shows the pattern forming apparatus according to an embodiment of the invention;

FIGS. 2A and 2B are drawings which show the structure of the syringe pump;

FIG. 3 is a flow chart which shows finger electrode forming processing performed by the apparatus which is shown in FIG. 1;

FIGS. 4A through 4E are drawings which schematically show how the nozzles move during the finger electrode forming processing which is shown in FIG. 3;

FIG. 5 is a drawing which shows the trajectory of the tips of the discharge nozzles during the finger electrode forming processing;

FIG. 6 is a timing chart which shows operations performed by the respective parts during the finger electrode forming processing; and

FIGS. 7A through 7F are drawings which show examples of the shapes of the anterior and the posterior ends of the line-like pattern.

### DETAILED DESCRIPTION OF THE PREFERRED EMBODIMENTS

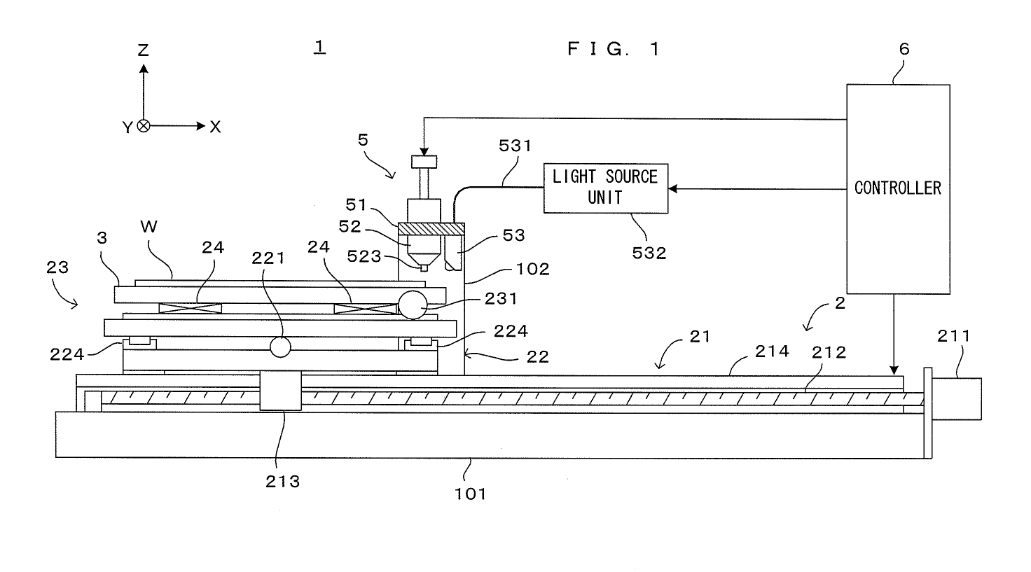

FIG. 1 is a drawing which shows the pattern forming apparatus according to an embodiment of the invention. The pattern forming apparatus 1 can be used for manufacturing a photoelectric conversion element which can be used as a solar battery for example, by forming a conductive electrode wiring pattern on a substrate W such as a single-crystal silicon wafer whose surface seats a photoelectric conversion layer.

In this pattern forming apparatus 1, a stage moving mechanism 2 is provided on a stand 101. A stage 3 holding the substrate W, owing to the stage moving mechanism 2, is capable of moving within an X-Y plane which is shown in FIG. 1. A frame 102 is mounted to the stand 101, straddling the stage 3. A head 5 is attached to the frame 102. A syringe pump 52 and a light irradiator 53 are mounted to a base 51 of the head 5. The syringe pump 52 holds in its inner space an application liquid which is liquid (or paste-like) and discharges the application liquid onto the substrate W. The light irradiator 53 irradiates UV light (ultra-violet light) toward the substrate W.

As described in detail later, the syringe pump 52 holds inside itself the application liquid which contains the material of an electrode pattern, and in accordance with a control command from a controller 6, discharges from discharge nozzles 523 the application liquid onto the substrate W. The application liquid may be a paste-like mixture which contains conductive and photo-curing substances such as conductive particles, an organic vehicle (a mixture of a solvent, a resin, a thickener, etc.) and a photopolymerization initiator. The conductive particles may for example be silver powder which is an electrode material, and the organic vehicle contains an organic solvent and ethyl cellulose which serve as a resin material.

The light irradiator 53 is connected to a light source unit 532 which generates UV light through an optical fiber 531. Although not shown, the light source unit 532 comprises at its light emitting part a shutter which can be opened and closed, and in accordance with whether the shutter is open or closed and to which degree the shutter is opened, the light source unit 532 can control on/off and the amount of emitted light. The controller 6 controls the light source unit 532. As the light irradiator 53 irradiates UV light upon the application liquid applied on the substrate W, the application liquid hardens while maintaining its cross sectional shape as it is right after applied.

The stage moving mechanism 2 comprises an X-direction moving mechanism 21 for moving the stage 3 in the X-direction, a Y-direction moving mechanism 22 for moving the stage 3 in the Y-direction, and a θ rotation mechanism 23 for rotating the stage 3 about an axis which is directed to the Z-direction. The X-direction moving mechanism 21 has a structure that a ball screw 212 is linked to a motor 211 while a nut 213 fixed to the Y-direction moving mechanism 22 is attached to the ball screw 212. A guide rail 214 is fixed above the ball screw 212. As the motor 211 rotates, the Y-direction moving mechanism 22 smoothly moves together with the nut 213 in the X-direction along the guide rail 214.

The Y-direction moving mechanism 22, too, comprises a ball screw mechanism and a guide rail 224 so that as a motor 221 rotates, the ball screw mechanism makes the θ rotation mechanism 23 move in the Y-direction along the guide rail 224. A motor 231 disposed to the θ rotation mechanism 23 rotates the stage 3 about the axis which is directed toward the Z-direction. The structure described above makes it possible to change the direction of relative movement of the first head part 5 and the second head part 7 to the substrate W and the directions of the first head part 5 and the second head part 7 to the substrate W. A controller 6 controls the respective motors of the stage moving mechanism 2.

A stage elevating/lowering mechanism 24 is disposed between the θ rotation mechanism 23 and the stage 3. In response to a control command from the controller 6, the stage elevating/lowering mechanism 24 moves the stage 3 up or down, whereby the substrate W is positioned at a designated height (which is a position in the Z-direction). The stage elevating/lowering mechanism 24 may be an actuator such as a solenoid and a piezo-electric element, a gear, combined wedges, etc.

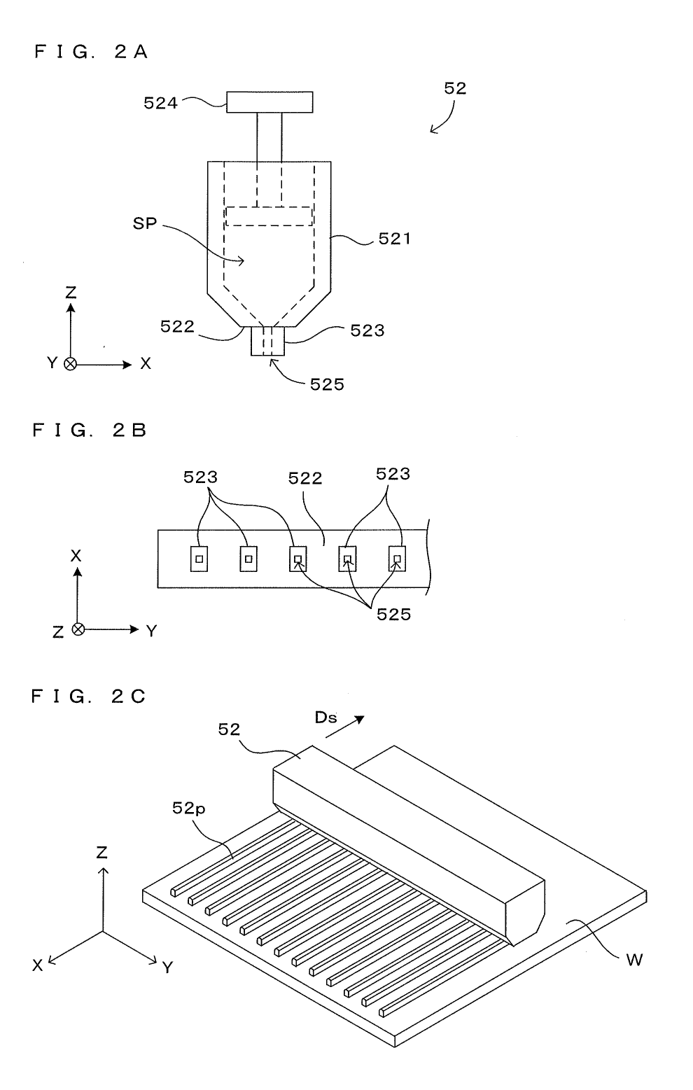

FIGS. 2A and 2B are drawings which show the structure of the syringe pump. To be more specific, FIG. 2A is a side view which shows the inner structure of the syringe pump 52 which is disposed in the head 5, and FIG. 2B is a drawing which shows the structure of the discharge nozzles disposed to the bottom surface of the syringe pump 52. FIG. 2C is a drawing which schematically shows how the syringe pump 52 applies the material. The interior of a housing 521 of the syringe pump 52 is a cavity whose top end opens toward above and whose bottom end links to the discharge nozzles 523 which are disposed to the bottom surface 522 of the housing 521. Through the opening at the top end of the cavity, a plunger 524 is inserted which moves up and down in accordance with a control command from the controller 6.

The application liquid of a predetermined composition is held inside the inner space SP of the housing 521 defined by the inner walls of the housing 521 and the plunger 524. As the plunger 524 is pressed down in response to a control command from the controller 6, the application liquid is discharged continuously from discharge outlets 525 which open toward below at the bottom end of the discharge nozzles 523 and link to the inner space SP.

As shown in FIG. 2B, the bottom surface 522 of the syringe pump 52 seats the plurality of discharge nozzles 523 which are apart from each other by a predetermined distance in the Y-direction. The opening shape of the discharge outlets 525 of each discharge nozzle 523 is roughly rectangular, and the length of one side of the shape is approximately the same as the line width of the application liquid to be applied. As shown in FIG. 2C, in this coating apparatus 1, in accordance with a control program created in advance, the application liquid 52p is discharged from the discharge outlets 525 of the discharge nozzles 523 while the controller 6 makes the substrate W on the stage 3 move horizontally within the XY plane, so that a predetermined line-like pattern is formed on the substrate W. As the plurality of the discharge outlets 525 are disposed side by side in the Y-direction, it is possible to form in one substrate scanning a pattern of plural lines which are away from each other in the Y-direction and parallel to each other. The direction in which the discharge nozzles 523 move relative to the stage 3 during movement of the stage 3 in the (+X)-direction, namely, the (−X)-direction will hereinafter be referred to as the scan movement direction Ds of the discharge nozzles 523.

Using the pattern forming apparatus 1 which has the structure described above, it is possible to form many patterns of mutually parallel thin lines with the application liquid discharged onto the substrate W. Further, hardening of the application liquid right after applied under the irradiated light maintains the cross sectional shape as it is immediately after application. Hence, when the opening shape of the discharge outlets 525 is properly selected, a pattern is formed whose height-to-width ratio, that is, whose aspect ratio is high. This is preferable for forming a finger electrode pattern as that described below for example on a light incident surface of the photoelectric conversion device.

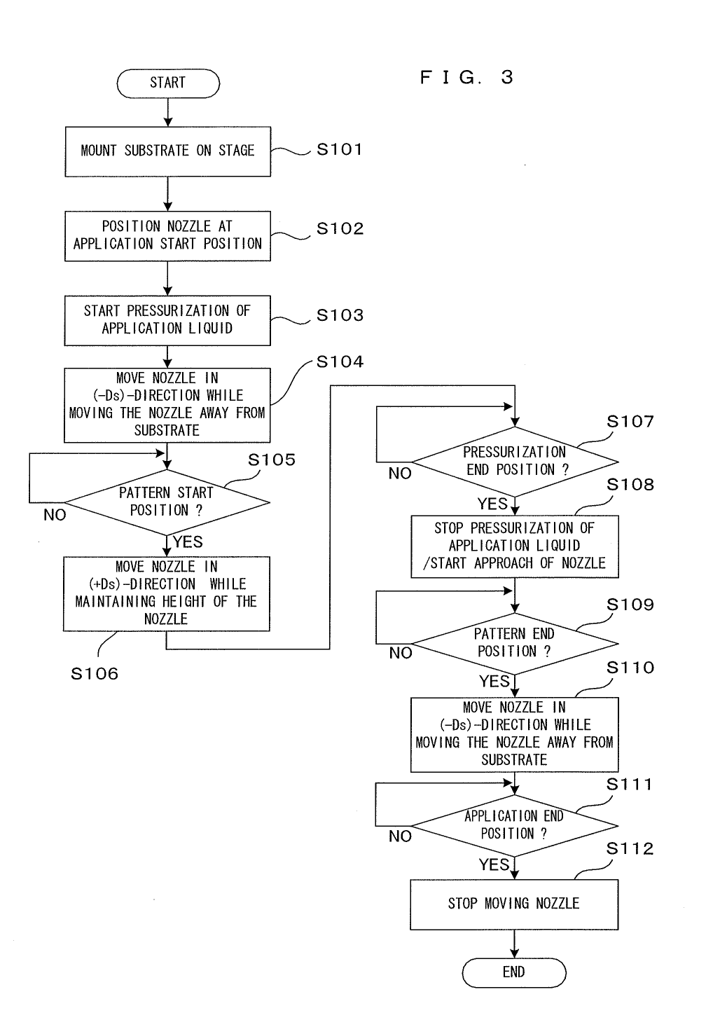

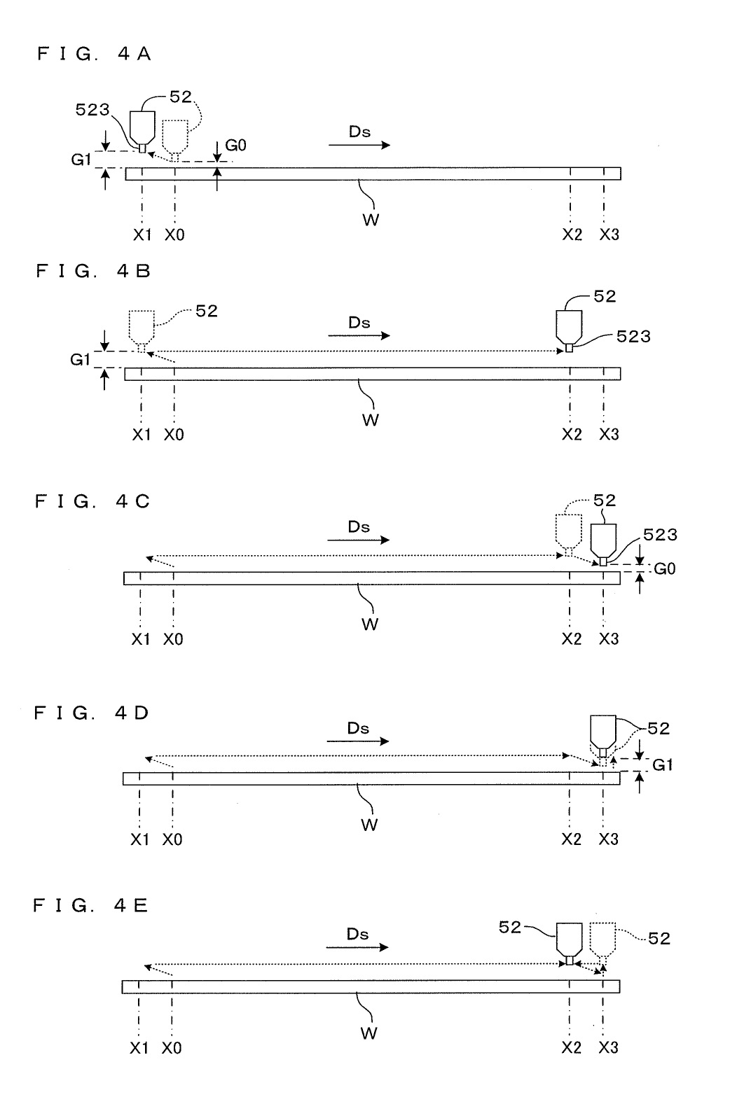

FIG. 3 is a flow chart which shows finger electrode forming processing performed by the apparatus which is shown in FIG. 1. FIGS. 4A through 4E are drawings which schematically show how the nozzles move during the finger electrode forming processing which is shown in FIG. 3. As described above, while the electrode forming apparatus shown in FIG. 1 has the structure that the stage 3 moves relative to the discharge nozzles 523, in a relative sense, that is equivalent to scan movement of the discharge nozzles 523 relative to the stage 3. Since that perception makes it easier to understand operations, the description below will be based upon an assumption that the discharge nozzles 523 move relative to the stage 3.

First, the substrate W which has a photoelectric conversion surface like a silicon substrate for solar battery for instance is loaded into the pattern forming apparatus 1, and mounted on the stage 3 with the photoelectric conversion surface directed toward above (Step S101). As the stage 3 then moves, the discharge nozzles 523 are positioned so that the horizontal positions of the discharge nozzles 523 come to a predetermined application start position (Step S102). The application start position is located somewhat inward from the edge of the surface of the substrate W but is right above the surface of the substrate W as indicated by the reference symbol X0 in FIG. 4A. Further, the gap G0 between the bottom edges of the discharge nozzles 523 and the surface of the substrate W has a relatively small value, for example, a smaller value than the height of a pattern to be formed.

Following this, the syringe pump 52 operates in this condition, thereby starting pressurization of the application liquid which is held inside (Step S103). This initiates discharging of the application liquid from the discharge outlets 525 which are at the tips of the discharge nozzles 523. In addition, the discharge nozzles 523 move in the (−Ds)-direction, namely, a direction toward the edge of the substrate W while moving upward, that is, in a direction away from the surface of the substrate W (Step S104).

Upon arrival of the horizontal position of the discharge nozzles 523 at a predetermined pattern start position X1 which is closer to the edge of the substrate than the application start position X0 (Step S105), the direction in which the discharge nozzles 523 horizontally move is reversed. Describing in more details, while maintaining the height of the nozzles to a constant value G1 (>G0) which is approximately the same as the height of a pattern to form or slightly larger than that, the discharge nozzles 523 are moved along the surface of the substrate W in the scan movement direction Ds (Step S106). This specification will refer to inversion of the horizontal movement direction of the discharge nozzles 523 in such a manner as “turning around.”

The application liquid discharged from the discharge outlets 525 and applied onto the substrate W in the form of lines turns around at the position X1 and is applied over the application liquid which was discharged onto the substrate right after the start of discharging. Therefore, on the substrate W after completion of the pattern, the position X1 substantially becomes the end point of the line-like pattern. In this sense, the position X1 becomes the pattern start position in reality. That is, where this pattern forming method is used, the application start position at which the application liquid is first applied is different from the pattern start position as it is upon completion.

It takes time for the discharged quantity to reach a predetermined value since the start of discharging, and the discharged quantity is not stable immediately after the start of application. This could potentially lead to disturbances such as thinning and breaking of the pattern which is formed with the application liquid right after the start of discharging. In contrast, according to this embodiment, such disturbances to the pattern are suppressed since the application liquid is applied in duplication as the discharge nozzles 523 turn around right after the start of discharging. To note particularly, it is possible to accurately align the pattern start position to a position which has been set in advance.

Following this, as shown in FIG. 4B, the discharge nozzles 523 keep moving horizontally in the scan movement direction Ds until they arrive at a predetermined pressurization end position X2 (Step S107). In consequence, the application liquid is applied as lines onto the substrate W. The light irradiator 53 irradiates UV light upon the application liquid which is on the substrate W, whereby the application liquid hardens and the electrode pattern is formed.

As the discharge nozzles 523 reach the pressurization end position X2, the syringe pump 52 stops pressurizing the application liquid (Step S108). Together with this, as shown in FIG. 4C, the discharge nozzles 523 start moving down and the discharge outlets 525 come closer to the substrate W. The pressurization end position X2 is located slightly inward from a pattern end position X3 which is set to be in the vicinity of the opposite side end to the pattern start position X1 in the surface of the substrate W.

As the horizontal position of the discharge nozzles 523 reaches the pattern end position X3 (Step S109), the discharge nozzles 523 move away from the substrate W (FIG. 4D). Concurrently with this, the discharge nozzles move horizontally once again in the (−Ds)-direction which is opposite to the scan movement direction (Step S110), and stop moving upon arrival at a predetermined application end position (FIG. 4E, Steps S111 and S112). Even after termination of pressurization of the application liquid at Step S108, the application liquid is still discharged at the discharge outlets 525 for a while because of the residual pressure within the inner space SP. However, the discharged quantity at this stage gradually decreases, and the rate of change of the discharged quantity is not always constant particularly right after stopping discharging.

The application end position described above is a position at which discharging of the application liquid from the discharge outlets 525 would have been stopped for sure upon arrival of the discharge nozzles 523 at the application end position, and this position may be experimentally determined in advance. As the discharge nozzles 523 turn around at the pattern end position X3 and the gradually decreasing application liquid is applied in duplication, it is possible to prevent the application liquid discharged in an unstable quantity right before the termination of discharging from disturbing the pattern. To note particularly, it is possible to precisely align the pattern end position to a position which has been set in advance. That is, with this pattern forming method, the position at which application of the application liquid ends is different from the pattern end position upon completion.

For the purpose of making control easy, the pressurization end position and the application end position are the same position X2 in this example. However, they do not have to be always the same position: they may be set separately from each other. In a similar fashion, although in this example the gap between the surface of the substrate W and the discharge nozzles 523 at the pattern end position X3 has the same value as the gap G0 at the application start position X0 and the gap after the movement of the nozzles away from the substrate has the same value as the gap G1 at the pattern start position X1, they may be set independently of each other.

By the way, the paste-like application liquid of this type has a property that its viscosity is high when not subjected to pressurization and therefore any shear force but greatly decreases when subjected to shear force (i.e., when pressurized): it is thixotropic (thixotropy). Examples of the numerical figures indicative of the viscosity of the application liquid in this embodiment are as given below.

The viscosity of the application liquid in a state that no pressurization is done on the application liquid as it is before the start of application, i.e., in a state that the syringe pump 52 is at the position denoted by the dotted line in FIG. 4A for instance is 1000 Pa·s (pascal seconds) for example. Meanwhile, the viscosity of the application liquid as it is pressurized inside the syringe pump 52 and constantly discharged from the discharge nozzles 523 as shown in FIG. 4B for instance is approximately 5 Pa·s for example. That is, pressurization accompanying shear force decreases the viscosity of the application liquid down to about 1/200. The application liquid applied onto the substrate W is irradiated with light, and the viscosity of the application liquid rises up to around 1×10⁵ Pa·s for example and becomes fixed.

Further, the viscosity of the application liquid as it is when pressurization of the application liquid stops and application finishes denoted by the solid line in FIG. 4E for instance is approximately 300 Pa·s. That is, the viscosity of the application liquid which is 5 Pa·s at the time that the syringe pump 52 reaches the pressurization end position X2 and pressurization of the application liquid stops increases approximately 60 times up to 300 Pa·s by the time discharging from the discharge nozzles 523 later stops.

While the discharged quantity may not become stable at the time of starting and finishing application even when a fluid which does not exhibit thixotropy or having only extremely small thixotropy such as the photo-resist fluid described in the patent document mentioned earlier is to be applied, it is possible to deal with that by slowing down the speed of the nozzle movement for instance. In contrast, in the event that a paste-like application liquid which exhibits clearer thixotropy is to be applied as in this embodiment, it is difficult to stabilize the application quantity only by such nozzle speed control or gap control. This is because the viscosity of the application liquid greatly changes (which is a non-linear change such as a square change and a cubic change) in a transitional state which may be at the time of starting or ending application. To obtain refined shapes at the anterior end and the posterior end of a pattern in such an instance, it is effective for the nozzles to turn around as in this embodiment.

Examples of the paste-like application liquid other than the examples described above represented by the numerical figures are, among others, a second example that the viscosity in a non-pressurized condition is 1000 Pa·s, the viscosity in a constantly pressurized condition is 5 Pa·s (which is 1/100 of the viscosity in the non-pressurized condition), and the viscosity at the end of application is 300 Pa·s (which is 60 times as large as the viscosity in the constantly pressurized condition) and a third example that the viscosity in the non-pressurized condition is 1000 Pa·s, the viscosity in the constantly pressurized condition is 400 Pa·s (which is 1/2.5 of the viscosity in the non-pressurized condition), and the viscosity at the end of application is 1000 Pa·s (which is 2.5 times as large as the viscosity in the constantly pressurized condition). In accordance with the findings the inventors of the invention have obtained, the invention is particularly effective for forming a pattern using the application liquid whose viscosity after the start of application decreases down to 1/2.5 of the pre-pressurization viscosity or below or the application liquid whose viscosity at the end of application increases up to 2.5 times of the viscosity during pressurization or beyond.

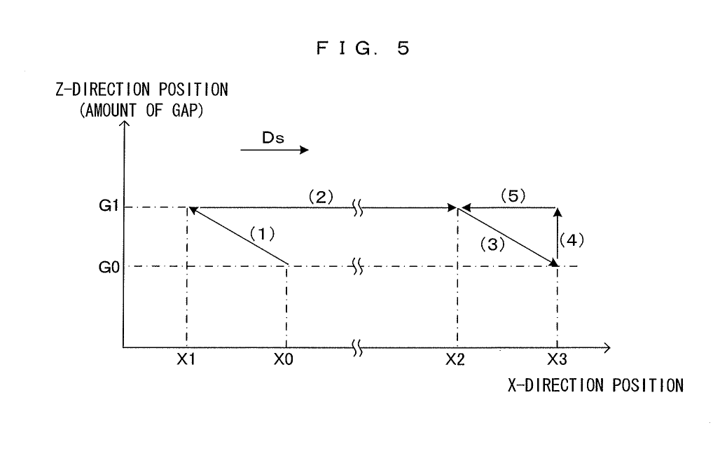

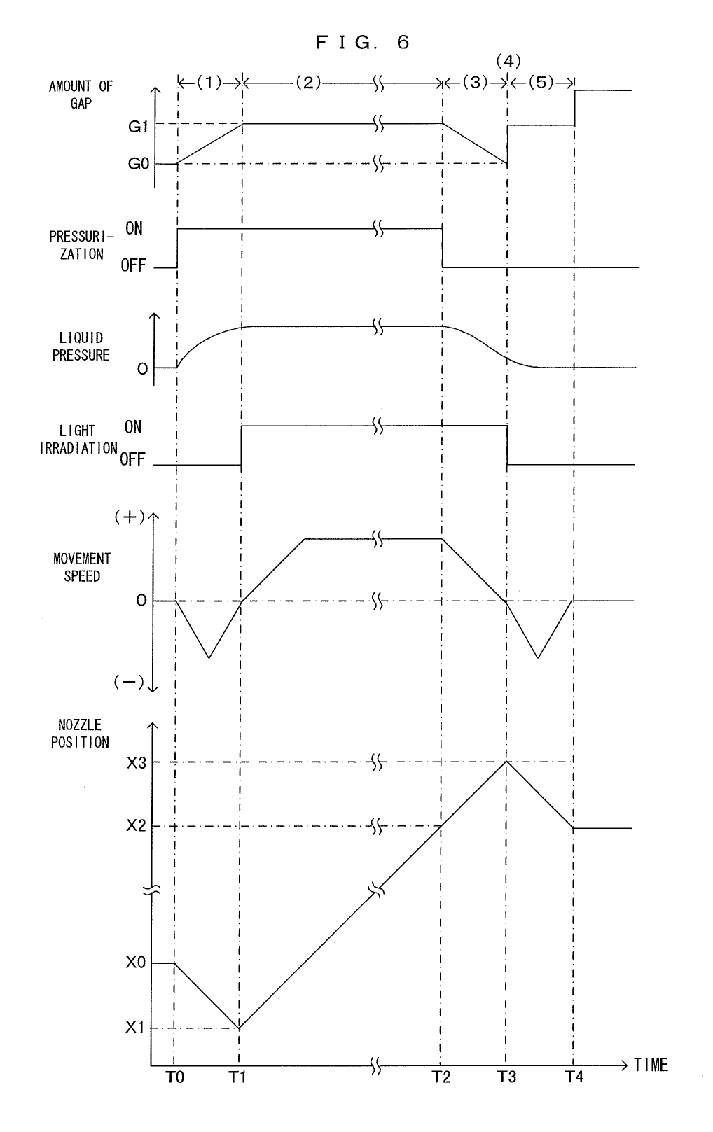

FIG. 5 is a drawing which shows the trajectory of the tips of the discharge nozzles during the finger electrode forming processing. FIG. 6 is a timing chart which shows operations performed by the respective parts during the finger electrode forming processing. The purpose of FIG. 6 is to schematically and qualitatively show how the positions, the speeds and the like of the respective parts change. Therefore, the vertical axis is expressed in arbitrary units, and the lengths or the gradients of the broken and the curved lines do not immediately represent the quantitative positions, the quantitative speeds or the like of the respective parts. The “MOVEMENT SPEED” indicates the horizontal movement speed of the discharge nozzles 523, and the speed of movement in the same direction as the scan movement direction Ds is a positive (+) speed, whereas the speed of movement in the opposite direction is a negative (−) speed. The numbers (1) through (5) correspond to those shown in FIG. 5.

At the application start position X0, the tips of the discharge nozzles 523 are opposed to the substrate W over the gap G0. As discharging of the application liquid starts, the discharge nozzles 523:

(1) move in the opposite direction to the scan movement direction Ds while moving away from the substrate W (with an increase of the Z-direction position);
(2) turn around at the pattern start position X1 and move in the scan movement direction Ds while maintaining the gap G1 from the substrate W;
(3) move in the scan movement direction Ds while approaching the substrate W after reaching the pressurization end position X2;
(4) move away from the substrate W (with the gap G1 at that time) after reaching the pattern end position X3 (with the gap G0 at that time);
(5) turn around back to the application end position X2.

After positioning of the discharge nozzles 523 at the application start position X0, pressurization of the application liquid is initiated at the time T0 (Step S103), whereby the liquid pressure inside the syringe pump 52 increases gradually and discharging of the application liquid from the discharge outlets 525 starts. The amount of the gap between the discharge nozzles 523 and the surface of the substrate W expands concurrently with the start of pressurization, and the discharge nozzles 523 move in the (−Ds)-direction (Step S104). At this stage, the light irradiator 53 has not irradiated light yet. In addition, acceleration and deceleration of the discharge nozzles 523 in the (−) direction is controlled so that the discharge nozzles 523 which have started moving from the application start position X0 stop at the pattern start position X1.

At the time T1 (with the gap G1) that the discharge nozzles 523 reach the pattern start position X1, the direction in which the discharge nozzles 523 move is reversed and the speed of movement of the discharge nozzles changes to (+) from (−) (Step S106). Irradiation of light from the light irradiator 53 is started concurrently with this. This achieves irradiation of UV light upon both the application liquid applied onto the substrate W before the turning-around and the application liquid applied after the turning-around on top of the application liquid applied before the turning-around, and these application liquids harden together and become the line-like electrode pattern. Further, as the application liquid is applied in duplication, changes of the discharged quantity right after the start of discharging are offset and disturbances to the pattern are suppressed.

After this, the discharge nozzles 523 move horizontally in the scan movement direction Ds while discharging at their discharge outlets 525 a constant quantity of the application liquid. At the time T2 that the discharge nozzles 523 arrive at the pressurization end position X2, pressurization of the application liquid by the syringe pump 52 is stopped (Step S108), and the liquid pressure inside the pump starts decreasing. Until the liquid pressure becomes zero, due to the residual pressure inside the pump, discharging from the discharge outlets 525 continues even in a progressively decreasing quantity. The gap between the discharge nozzles 523 and the substrate W is reduced gradually together with the discontinuation of pressurization, and for the purpose of stopping the movement at the pattern end position X3, the speed of the movement of the discharge nozzles 523 is decreased gradually.

It is preferable that the time required for the discharge nozzles 523 to move from the pressurization end position X2 to the pattern end position X3 is approximately half the time from the discontinuation of pressurization of the application liquid until the complete discontinuation of discharging of the application liquid. This makes the application liquid start losing its discharged quantity from the pressurization end position X2 before turning around, and the discharged quantity becomes zero at the application end position (=the pressurization end position X2) which is after the turning-around. This minimizes disturbances of the shape of the pattern at the edges formed as the application liquid is provided in duplication before and after the turning-around. In short, it is possible to maximize the effect of making the pressurization end position and the application end position the same position.

The discharged quantity of the application liquid gradually decreases after the discontinuation of pressurization and becomes unstable particularly right before the end of discharging, potentially giving rise to a problem that chunks of the application liquid fall off onto the substrate W, the pattern becomes broken, etc. However, it is possible to solve the problem when the speed of the movement of the discharge nozzles 523 is decreased and the gap from the substrate W is reduced. At the time T3 that the discharge nozzles 523 reach the pattern end position X3 (with the gap G0 at this time), the gap is returned back to G1, the discharge nozzles 523 turn around, and the direction in which the discharge nozzles 523 move is switched to the opposite direction (−Ds) which is opposite to the scan movement direction. As a result of this, the application liquid which is discharged due to the residual pressure is applied over the pattern which has already been formed.

The light irradiator 53 stops irradiating light at the time T3, and no light is irradiated during the turning-around operation. Hence, the application liquid applied during this flows and spreads out instead of immediately hardening. Since the discharged quantity right before the discontinuation of discharging greatly changes as described before, if the application liquid as it is right after applied is allowed to harden, the pattern will have an irregular shape. This can however be prevented by not irradiating light. Since the discharged quantity at this stage is already sufficiently small, only small disturbances are made to the pattern shape because of spreading of the application liquid which has not yet hardened. As the solvent component volatilizes, the application liquid which has not hardened yet also becomes non-fluid after a while, and therefore, spreading of the application liquid is momentary.

The reason of moving the discharge nozzles 523 away from the substrate W at the time T3 is to prevent the bottom edges of the discharge nozzles 523 from contacting the pattern which has been formed during the turning-around operation. Meanwhile, even at this point, discharging of the application liquid has not completed yet. Hence, when the gap is too large, the application liquid may fall down as drops onto the substrate W or the surface tension may allow the discharge nozzles 523 to draw out the application liquid and give rise to trailing. The gap at this stage is approximately the same as the gap G1 which is the gap during the horizontal movement, but this is not limiting.

By the time T4 that the discharge nozzles 523 reach the application end position X2 (=the pressurization end position), discharging of the application liquid from the discharge nozzles 523 has completely stopped. In short, formation of the pattern has completed. Hence, the discharge nozzles 523 stop moving, and in an effort not to interfere with unloading of the substrate W, the discharge nozzles 523 further move away. At this stage, the discharge nozzles 523 may retract back to predetermined retract positions.

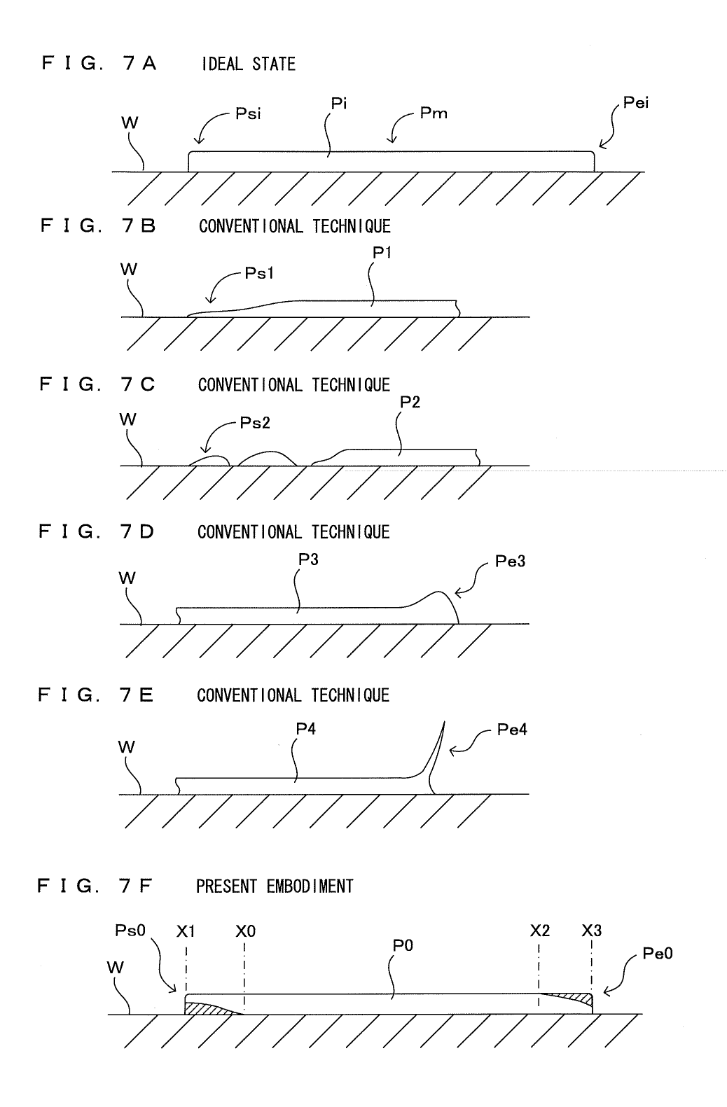

FIGS. 7A through 7F are drawings which show examples of the shapes of the anterior and the posterior ends of the line-like pattern. An ideal pattern shape has, as denoted at Pi in FIG. 7A, approximately the same width and height at both an anterior end Psi and a posterior end Pei as those of a middle part Pm. However, according to the conventional techniques which require that the application start position is the same as the pattern start position, since the discharged quantity right after the start of discharging is unstable, there may be instances like the pattern P1 shown in FIG. 7B that the anterior end Ps1 becomes thin or narrow or like a pattern P2 shown in FIG. 7C that an anterior end Ps2 is formed intermittently. In such instances, in addition to disturbances to the pattern shape, the pattern start position varies depending upon the viscosity of the application liquid, etc.

Meanwhile, according to the conventional techniques which require that the application end position and the pattern end position are the same, the pattern may be disturbed due to the instability of the discharged quantity right before the discontinuation of discharging. Besides, as the application liquid falls down after temporarily staying around the discharge outlets, a posterior end Pe3 may swell up as in the case of a pattern P3 which is shown in FIG. 7D. Further, due to the surface tension of the application liquid, the application liquid follows the discharge nozzles which move away, and as in a pattern P4 which is shown in FIG. 7E, the application liquid may get drawn thin near a posterior end Pe4 and have thread-like trailing.

In contrast, with respect to the pattern P0 formed according to this embodiment shown in FIG. 7F, discharging of the application liquid is initiated at the application start position X0 which is closer to a central part of the substrate than the pattern start position X1, and the discharge nozzles 523 move toward the edge of the substrate W once and turn around at the pattern start position X1. Due to this, disturbances of the shape are small at an anterior end Ps0 and the pattern start position X1 of the pattern remains constant regardless of the instability of discharging. The portion shaded with slanted lines at the posterior end Ps0 is indicative of the application liquid discharged prior to the turning-around.

Further, in this embodiment, the discharge nozzles 523 turn around near a posterior end Pe0 of the pattern P0 as well. Hence, the pattern end position X3 is constant, which makes it possible to prevent swelling or trailing at the posterior end Pe0 of the pattern and obtain an ideal shape of the edge. In FIG. 7F, the portion shaded with the slanted lines at the posterior end Pe0 of the pattern is indicative of the application liquid discharged after the turning-around.

Further, while the gap between the discharge nozzles 523 and the substrate W gradually increases from a small value near the pattern front end before the turning-around, pressurization of the application liquid is stopped in the vicinity of the posterior end and the gap between the discharge nozzles 523 and the substrate W is decreased. It is therefore possible to prevent disturbances to the pattern during a period in which the discharged quantity is unstable right after the start of pressurization and after the discontinuation of pressurization. The intention of this is to make the application liquid stay between the discharge outlets 525 and the surface of the substrate W due to the surface tension as the discharge outlets 525 are moved closer to the substrate W, and by moving the discharge nozzles 523 in this condition, to prevent intermittent falling of the application liquid onto the substrate W. In this fashion, it is possible to stably form a continuous pattern right after the start of discharging and after the discontinuation of pressurization at which times the discharged quantity is small.

With respect to the substrate W which thus seats the line-like pattern which will become finger electrodes, it is desirable to perform sintering next and make the pattern harden more securely. This makes it possible to securely harden the application liquid near the posterior end which was not irradiated with light. In addition, as bus electrodes intersecting the finger electrodes are formed, it becomes capable of serving as a solar battery module. The finger electrodes may be formed in the manner described above on the substrate which already seats the bus electrodes.

As described above, the stage 3 and the discharge nozzles 523 respectively function as “the holder” and “the nozzle(s)” of the invention while the stage moving mechanism 2 functions as “the mover” and “the gap controller” of the invention.

The invention is not limited to the embodiments described above but may be modified in various manners in addition to the embodiments above, to the extent not deviating from the object of the invention. For instance, the embodiment above requires that, under the common technical concept of maintaining the shape at the edges owing to the turning-around of the nozzles, the nozzles turn around and the gap is controlled at each one of the anterior end and the posterior end of the pattern. However, the effect of the embodiment at the anterior end of the pattern and that at the posterior end of the pattern are independent of each other. Therefore, processing as that described above may be applied only to the anterior end or the posterior end in accordance with the viscosity of the application liquid, the shape of the pattern, etc.

Although gap control before and after the turning-around is effective in enhancing the effect of the turning-around, this is not an essential requirement in the invention. Hence, even when gap control, namely, how the nozzles move closer to and away from the substrate is different from that according to the embodiment described above, the technique of making the nozzles turn around at one of the anterior end and the posterior end of the pattern at least falls under the scope of the invention. As denoted at the broken line in FIG. 6 for instance, the amount of the gap between the discharge nozzles 523 and the substrate W as it is at the start of discharging may be set to G1 and the operation of turning the discharge nozzles around alone may be performed.

Further, according to the embodiment above, as the stage 3 seating the substrate W moves in a state that the discharge nozzles 523 are fixed, the discharge nozzles 523 and the substrate W are made to move relative to each other in the horizontal direction and the vertical direction. However, the discharge nozzles 523 may be moved instead. As the discharged quantity changes in the vicinity of the edges of the pattern even when the nozzles are fixed as described above, it is not preferable to move or vibrate the nozzles. In this sense, the structure as that according to the embodiment above of moving the substrate W is more preferable.

Further, according to the embodiment above, the application liquid contains the photo-curing material and irradiation of light upon the application liquid which has been applied helps promote hardening. However, the invention can be applied also to an application technique which does not accompany photo-curing.

Further, although the embodiment above requires forming wiring only on one surface of the substrate W, the invention can be applied also to formation of wiring on the both surfaces of the substrate W.

Further, according to the embodiment above, the finger electrode wiring pattern is formed on the silicon substrate in manufacturing a photoelectric conversion device which serves as a solar battery. However, the substrate is not limited to silicon. The invention can be applied also to, for example, a thin-film solar battery formed on a glass substrate, formation of patterns in other devices than solar batteries, etc.

In a first aspect regarding the pattern forming method according to the invention, the discharged quantity of the application liquid may be gradually decreased before the relative position of the nozzle to the surface of the substrate arrives at the pattern end position. Since the application liquid is applied in duplication as the nozzle turns around in the vicinity of the pattern end position, gradual reduction of the application liquid prevents increasing of the thickness of the pattern which will otherwise occur due to duplicated application.

Where pressurization of the application liquid inside the nozzle makes the application liquid discharged from the discharge outlet, pressurization of the application liquid may be stopped to reduce the discharged quantity accordingly for instance. Termination of pressurization of the application liquid does not immediately stop discharging, and the pressure which remains (residual pressure) maintains discharging for more while even though the discharged quantity decreases. Utilizing this, as pressurization of the application liquid is stopped before the nozzle reaches the pattern end position, discharging owing to the residual pressure permits forming the remaining pattern.

Alternatively, the nozzle may be moved to the pattern end position while gradually decreasing a movement speed of the nozzle relative to the substrate simultaneously with or after the start of reduction of the discharged quantity. As the discharged quantity of the application liquid gradually becomes small, if the nozzle movement speed is fast, the pattern may get broken. When the nozzle movement speed is gradually decreased, it is possible to avoid such a problem.

Alternatively, for example, the nozzles may be moved to the pattern end position while gradually reducing a gap between the discharge outlet and the surface of the substrate simultaneously with or after the start of reduction of the discharged quantity, and the nozzle arrives at the pattern end position, the gap between the discharge outlet and the surface of the substrate may be increased and the nozzle may be moved in the opposite direction to the scan movement direction. It is possible to prevent the pattern from becoming broken also by bringing the discharge outlet and the surface of the substrate close to each other when the discharged quantity of the application liquid becomes small. In addition, since the discharge outlet and the substrate move away from each other at the time of the turning-around, it is possible to prevent the nozzle from contacting the pattern which has already been formed.

Further, the relative position of the nozzle to the surface of the substrate in the scan movement direction at a time of the start of reduction of the discharged quantity may be the same as the relative position of the nozzle to the surface of the substrate in the scan movement direction at a time that the discharged quantity becomes zero. When this is done, application at the time of the turning-around compensates reduction of the width or the height of the pattern which is attributable to discharged quantity reduction, and therefore, it is possible to form a pattern whose width, height and the like are more stable.

Further, in a second aspect regarding the pattern forming method according to the invention, for instance, right after starting discharging the application liquid from the discharge outlet, a gap between the discharge outlet and the surface of the substrate may be gradually increased while moving the nozzle in the opposite direction to the scan movement direction. Right after the start of discharging as well, the problem that the pattern gets broken because of the unstable discharged quantity of the application liquid is similar to or more apparent than at the time of terminating discharging. To have the discharge outlet close to the substrate right after the start of discharging and to gradually widen the gap is effective for preventing the pattern from getting broken.

In each such invention described above, a liquid containing a photo-curing material may be used as the application liquid and light may be irradiated upon the application liquid discharged onto the surface of the substrate. Since this makes it possible for the application liquid applied to the substrate to harden before it spreads out, control of the cross sectional shape of the pattern is easy, which is preferable for forming a pattern whose width-to-height ratio, namely, aspect ratio in particular is high.

Further, the pattern forming apparatus according to the invention may comprise for instance a gap controller which controls a gap between the discharge outlet and the surface of the substrate. When it is thus made possible to control the gap between the discharge outlets and the surface of the substrate, it is possible to try preventing a broken pattern at the time of starting and finishing discharging of the application liquid.

The invention is particularly preferably applicable to a technique for stably forming a predetermined pattern on a substrate, e.g., a thin pattern such as a finger electrode wiring pattern on a solar battery substrate.

Although the invention has been described with reference to specific embodiments, this description is not meant to be construed in a limiting sense. Various modifications of the disclosed embodiment, as well as other embodiments of the present invention, will become apparent to persons skilled in the art upon reference to the description of the invention. It is therefore contemplated that the appended claims will cover any such modifications or embodiments as fall within the true scope of the invention.

What is claimed is:

1. A pattern forming method, comprising:
forming a stripe-shaped pattern on a surface of a substrate by discharging an application liquid containing a pattern forming material continuously from a discharge outlet of a nozzle to the surface of the substrate while moving the nozzle along and relative to the surface of the substrate in a predetermined scan movement direction; and
stopping the discharge of the application liquid from the discharge outlet while moving the nozzle along the surface of the substrate in an opposite direction to the scan movement direction after a relative position of the nozzle to the surface of the substrate arrives at a predetermined pattern end position.

2. The pattern forming method of claim 1, wherein before the relative position of the nozzle to the surface of the substrate arrives at the pattern end position, the discharged quantity of the application liquid is gradually decreased.

3. The pattern forming method of claim 2, wherein the application liquid is discharged from the outlet due to pressurization of the application liquid inside the nozzle, and the discharged quantity is reduced by stopping pressurization of the application liquid.

4. The pattern forming method of claim 2, wherein simultaneously with or after the start of reduction of the discharged quantity, the nozzle is moved to the pattern end position while gradually decreasing a movement speed of the nozzle relative to the substrate.

5. The pattern forming method of claim 2, wherein simultaneously with or after the start of reduction of the discharged quantity, the nozzle is moved to the pattern end position while gradually reducing a gap between the discharge outlet and the surface of the substrate, and as the nozzle arrives at the pattern end position, the gap between the discharge outlet and the surface of the substrate is increased and the nozzle is moved in the opposite direction to the scan movement direction.

6. The pattern forming method of claim 2, wherein the relative position of the nozzle to the surface of the substrate in the scan movement direction at a time of starting reduction of the discharged quantity is the same as the relative position of the nozzle to the surface of the substrate in the scan movement direction at a time that the discharged quantity becomes zero.

7. The pattern forming method of claim 1, wherein a liquid containing a photo-curing material is used as the application liquid, and light is irradiated upon the application liquid discharged onto the surface of the substrate.

8. A pattern forming method, comprising:
moving the nozzle along and relative to the surface of the substrate in a predetermined scan movement direction; and
discharging an application liquid containing a pattern forming material continuously from a discharge outlet of the nozzle to the surface of the substrate while moving the nozzle in the scan movement direction, thereby forming a stripe-shaped pattern on the surface of the substrate, wherein
the nozzle is moved along the surface of the substrate in the opposite direction to the scan movement direction for a predetermined period since a start of discharging, and following this, the nozzle is moved along the surface of the substrate in the scan movement direction.

9. The pattern forming method of claim 8, wherein right after starting discharging of the application liquid from the discharge outlet, while moving the nozzle in the opposite direction to the scan movement direction, a gap between the discharge outlet and the surface of the substrate is gradually increased.

10. The pattern forming method of claim 8, wherein a liquid containing a photo-curing material is used as the application liquid, and light is irradiated upon the application liquid discharged onto the surface of the substrate.

11. A pattern forming apparatus, comprising:
a holder which holds a substrate;
a nozzle which comprises a discharge outlet for continuously discharging an application liquid which contains a pattern forming material; and
a mover which moves the nozzle along and relative to a surface of the substrate, which is held by the holder, in a predetermined scan movement direction,
wherein either right after starting or right before stopping discharging the application liquid from the outlet, the mover moves the nozzle along the surface of the substrate in the opposite direction to the scan movement direction for a predetermined period.

12. The pattern forming apparatus of claim 10, comprising a gap controller which controls a gap between the discharge outlet and the surface of the substrate.
